(19) United States
(12) Patent Application Publication
(10) Pub. No.: US 2024/0193333 A1
(43) Pub. Date: Jun. 13, 2024

(54) Multilevel distributed parallel computing method for integrated circuit board simulation

(71) Applicant: XPEEDIC CO., LTD., SHANGHAI (CN)

(72) Inventors: Wenliang DAI, SHANGHAI (CN); Liguo JIANG, SHANGHAI (CN); Feng LING, SHANGHAI (CN); Jian ZHANG, SHANGHAI (CN)

(21) Appl. No.: 18/553,424

(22) PCT Filed: Sep. 6, 2022
(86) PCT No.: PCT/CN2022/117348

§ 371 Date: Sep. 29, 2023

(30) Foreign Application Priority Data
Sep. 7, 2021 (CN) 202111046994.7

(51) Int. Cl. G06F 30/3308; G06F 30/23

(52) U.S. Cl. CPC G06F 30/3308; G06F 30/23

(57) ABSTRACT

A multilevel distributed parallel computing method for integrated circuit board simulation, belonging to the technical field of integrated circuit simulation, includes following steps: S100, calculating number of nodes; S200, allocating tasks; S300, calculating and solving; and S40, judging convergence. By dynamically paralleling multiple computers, the present invention can maximize utilization of computing resources, improve simulation efficiency, and finally achieve a purpose of shortening design cycle. And in the simulation process, through the dynamic result analysis method, frequency points that need to be solved can be actually found, and accurate full-band results with the least number of solutions is completed.

### TECHNICAL FIELD

The present invention belongs to the technical field of integrated circuit simulation, and particularly relates to a multilevel distributed parallel computing method for integrated circuit board simulation.

### Background Technology

In designs of chip packaging and Printed Circuit Board (PCB), with increase on performance requirements, performance requirements at high frequency become more and more demanding. In this case, analysis methods of lumped circuit are no longer applicable, and full-wave electromagnetic field analysis methods must be used to obtain reliable performance simulation results.

In design processes, simulation verification is indispensable. Among many computational electromagnetic methods, Finite Element Method (FEM) is widely used because of wide adaptability thereof. However, currently simulation systems generally consume too much time, which seriously affects the design efficiency.

After searching, a Chinese patent invention (application number is CN202011068618.3, and the filing date is 20201009) is found. The invention disclosed a method for calculating an electromagnetic field of a three-dimensional integrated circuit based on mixed-order finite element and device thereof. The method comprises the following steps: obtaining a first tetrahedral grid of a three-dimensional very-large-scale integration (VLSI) multi-scale layout according to the Delaunay grid division algorithm; determining a maximum side length of grid cells in the grid, and subdividing the first tetrahedral grid to form a second tetrahedral grid; based on the above, a first-order element and a finite element stiffness matrix thereof is established, and a initial value of the electromagnetic field of the three-dimensional VLSI is solved according to field-circuit coupling; based on the second tetrahedron grid, a mixed-order cell is established according to the grid cells whose initial value change speed exceeds and does not exceed a preset value and the grid cells in a small-scale area of a three-dimensional integrated circuit layout; according to the mixed-order element, the finite element stiffness matrix is established to calculate the electromagnetic field of the three-dimensional VLSI.

However, shortcomings of the application above comprise:
1) The method takes a long time; 2) The process is complicated.

### SUMMARY OF THE INVENTION

1. Technical problems to be solved in the present invention

The present invention provides a multilevel distributed parallel computing method for integrated circuit board simulation, which aims to solve the problem that the efficiency of the existing three-dimensional very-large-scale integration (VLSI) is too low.

2. Technical solutions

In order to achieve the above purpose, a technical solution provided by the present invention is as follows:

A multilevel distributed parallel computing method for integrated circuit board simulation in the present invention; the method comprises following steps:
S100, calculating a number of nodes;
S200, allocating tasks;
S300, calculating and solving; and
S400, judging convergence.

Preferably, in step S100, calculating the number of nodes comprises specifically determining the number of nodes opened on corresponding computing nodes by taking user parameters and mesh generation results as inputs and estimating memory consumption and user control.

Preferably, in step S200, the tasks allocation comprises specifically: selecting appropriate simulation frequency points from simulation segments as required by users according to the number of nodes determined in step S100and distributing to the computing nodes.

Preferably, in step S300, calculating and solving comprises specifically solving distribution of electric fields and magnetic fields in the solution area at each of the computing nodes by a finite element method and extracting performance parameters of a circuit according to distribution of electromagnetic fields in a solution area for subsequent simulations.

Preferably, in step S400, the convergence judgment comprises specifically judging whether current results meet convergence conditions according to convergence conditions specified by the users.

Preferably, in step S300 the finite element method is used, specifically a finite element wave equation as shown here:

$${\int }_{Ω} {W}_{i} \cdot ⌊ ∇ \times ( \frac{1}{{μ}_{r}} ∇ \times E ) - {k}_{0}^{2} {ε}_{r} E ⌋ d Ω = - {jk}_{0} {Z}_{0} {\int }_{Ω} {W}_{i} \cdot {J}_{imp} d Ω$$

Preferably, the distribution in the solution area in step S300 comprises grid division of the solution area; the grid division of the solution area comprises but is not limited to tetrahedron division; and the tetrahedron division is as follows:
by introducing a barycentric coordinate system and taking a tetrahedron unit year as an example, four vertices of each tetrahedron can be expressed as: (L₁^{e}, L₂^{e}, L₃^{e}, L₄^{e}); the tetrahedron comprises six edges with serial numbers 1, 2, 3, 4, 5 and 6, and the edges are placed as a vector basis function: Nᵢ^{e}=Wᵢ_{₁}ᵢ_{₂}|ᵢ^{e}=(Lᵢ_{₁}^{e}∇Lᵢ_{₁}^{e}−Lᵢ_{₁}^{e}∇Lᵢ_{₁}^{e})|ᵢ^{e};
among which, lᵢ^{e} represents a length of an ith edge; a unit vector e1 is defined as a unit vector pointing from a node 1 to a node 2, and a gradient relative to gravity center coordinates can be described by following formulas e₁·∇L₁^{e}=−1/l₁² and e₁·∇L₂^{e}=1/l₁^{e}.

Preferably, an integral region in the equation is divided into several sub-regions Ωₙ, and a matrix equation can be obtained by using the finite element analysis method; a left term of the matrix equation comprises two terms:

$${E}_{ij}^{e} = \int \int {\int }_{{V}^{e}} ( ∇ \times {N}_{i}^{e} ) \cdot ( ∇ \times {N}_{j}^{e} ) dV \\ {F}_{ij}^{e} = \int \int {\int }_{{V}^{e}} {N}_{i}^{e} \cdot {N}_{j}^{e} dV$$

a right term of the matrix equation is as follows:

b=−jk₀Z₀f_{edgek}Nₖ*d1=−jk₀Z₀ξ

according to the above equations, a sparse matrix equation Ax=b can be obtained. The matrix equation can be solved by multi frontal algorithm; solution resources used in this step can be a local computer or multi-computer parallel, which can be dynamically adjusted according to fitting results.

Preferably, the multilevel distributed parallel computing method in the present invention also comprises recovering the solution results and fitting frequency response with a formula

$$f ( s ) \approx {\sum }_{n = 1}^{N} \frac{{c}_{n}}{s - {a}_{n}} + d + sh ,$$

where cₙ is a residue term and an is a pole; a fitting process comprises multiplying a left end and a right end of the defined frequency response by an unknown function

$$σ ( s ) = {\sum }_{n = 1}^{N} \frac{s - \overline{{a}_{n}}}{} + 1$$

simultaneously, and an overdetermined matrix equation about unknown quantities cₙ, d, h, and [symbol] be obtained by substituting a few frequency points into the unknown function:

$$( {\sum }_{n = 1}^{N} \frac{{c}_{n}}{s - \overline{{a}_{n}}} + d + sh ) = ( {\sum }_{n = 1}^{N} \frac{s - \overline{{a}_{n}}}{} + 1 ) f ( s )$$

an unknown quantity obtained by solving the unknown function can be used to describe a formula of the frequency response:

$$f ( s ) = \frac{{( σ f )}_{fit} ( s )}{{σ}_{fit} ( s )} = h \frac{{\sum }_{n = 1}^{N + 1} ( s - {z}_{n} )}{{\sum }_{n = 1}^{N} ( s - )}$$

using a solution of σ (s)=0 as a new pole, a new overdetermined matrix equation can be generated to solve unknown quantities cₙ, d, and h.

Preferably, the multilevel distributed parallel computing method in the present invention also comprises judging whether current results meets convergence conditions according to the convergence conditions specified by the users; If errors are large, according to the available computing resources, selecting dynamically a number of frequency points and allocating to the computing nodes; If the errors approach the convergence conditions, estimating the number of frequency points to be solved, and allocating dynamically node computing resources according to the number of frequency points and the computing nodes, so that multiple computing nodes can solve the system matrix of a certain frequency point at the same time.

3. Beneficial effects

Compared with the prior art, the technical solution provided by the present invention has the following beneficial effects:

By dynamically paralleling multiple computers, the multilevel distributed parallel computing method for integrated circuit board simulation of the present invention can maximize utilization of computing resources, improve simulation efficiency, and finally achieve a purpose of shortening design cycle. And in the simulation process, through the dynamic result analysis method, we can accurately find frequency points that need to be solved, and complete accurate full-band results with a least number of solutions.

### DESCRIPTION OF DRAWINGS

FIG. 1 is a flowchart of a multilevel distributed parallel computing method for integrated circuit board simulation of the present invention;

FIG. 2 is a flowchart of the embodiment 1;

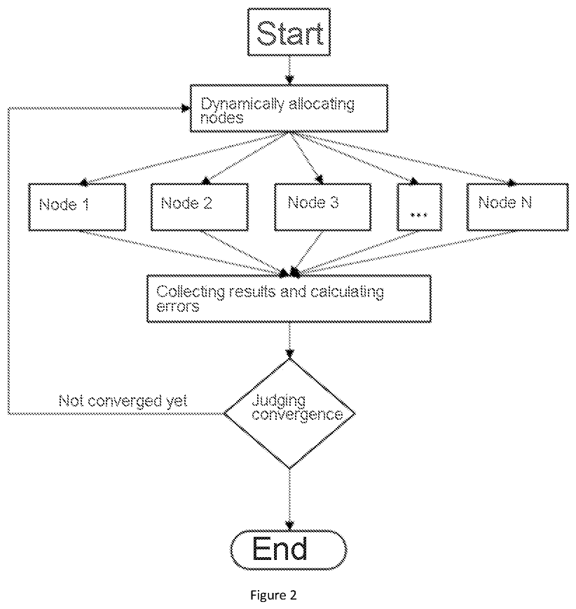

FIG. 3 is a schematic diagram of acceleration efficiency after using the method of the present invention is used;

FIG. 4 is a schematic diagram of iteration times of dynamic frequency points in a method flow of the present invention; and

FIG. 5 is a schematic diagram of calculation results and interpolation results of the method of the present invention.

### EMBODIMENTS

In order to facilitate the understanding of the present invention, the present invention will be described more fully below with reference to the relevant drawings, in which several embodiments of the present invention are given. However, the present invention can be realized in many different forms, and is not limited to the embodiments described here. On the contrary, these embodiments are provided to make the disclosure of the present invention more thorough and comprehensive. It should be noted that when an element is described to be “fixed” to another element, it can be directly on another element or there can also be an itermediate element; when an element is described to be “connected” to another element, it can be directly connected to another element or there may be intervening elements at the same time; the terms “vertical”, “horizontal”, “left” and “right” and similar expressions used in the present invention are for illustration only.

Unless otherwise defined, all technical and scientific terms used herein have the same meaning as commonly understood by those skilled in the technical field of the present invention; the terminology used in the description of the present invention herein is only for purpose of describing specific embodiments, and is not intended to limit the present invention; as used herein, the term “and/or” comprises any and all combinations of one or more related listed items.

### Embodiment 1

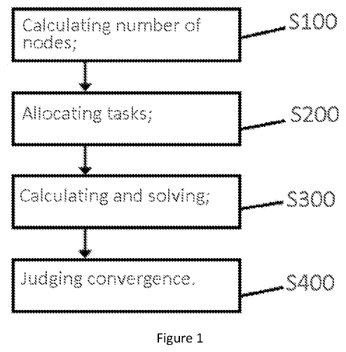

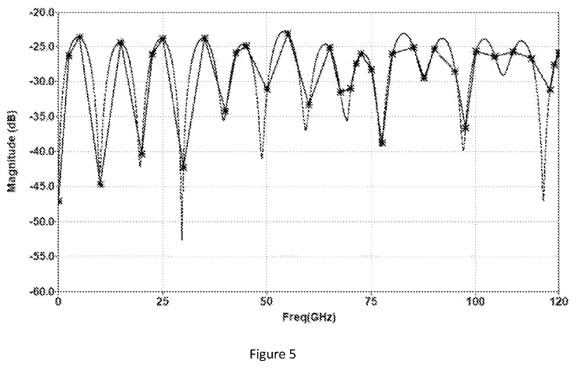

Referring to FIG. 1 and FIG. 5, multilevel distributed parallel computing method for integrated circuit board simulation in the present embodiment comprises following steps:
S100, calculating number of nodes;
S200, allocating tasks;
S300, calculating and solving; and
S400. judging convergence.

By dynamically paralleling multiple computers, the method of the present invention can maximize utilization of computing resources, improve simulation efficiency, and finally achieve a purpose of shortening design cycle. And in the simulation process, through the dynamic result analysis method, we can accurately find frequency points that need to be solved, and complete accurate full-band results with a least number of solutions.

In the following paragraphs, the steps in the present application solutions are introduced in detail.

In step S100, a number of nodes opened on corresponding computing nodes is determined by taking user parameters and mesh generation results as inputs and estimating memory consumption and user control.

In step S200, the tasks allocation is specifically conducted by the following: according to the number of nodes determined in step S100, and appropriate simulation frequency points are selected from simulation segments required by users and distributed to the computing nodes.

In step S300, each computing node accurately solves distribution of electric fields and magnetic fields in the solution area by a finite element method, and extracts performance parameters of the circuit according to distribution of electromagnetic fields in the solution area for subsequent simulations.

In step S400, the convergence judgment is specifically to judge whether current results meet convergence conditions according to the convergence conditions specified by the user.

Step S300 adopts the finite element method, specifically the following finite element wave equation:

$${\int }_{Ω} {W}_{i} \cdot [ ∇ \times ( \frac{1}{{μ}_{r}} ∇ \times E ) - {k}_{0}^{2} {ε}_{r} E ] d Ω = - {jk}_{0} {Z}_{0} {\int }_{Ω} {W}_{i} \cdot {J}_{imp} d Ω$$

The distribution in the solution area in step S300 comprises grid division of the solution area; the grid division of the solution area comprises but is not limited to tetrahedron division; and the tetrahedron division is as follows:

By introducing a barycentric coordinate system and taking a tetrahedron unit year as an example, four vertices of each tetrahedron can be expressed as: (L₁^{e}, L₂^{e}, L₃^{e}, L₄^{e}); the tetrahedron comprises six edges with serial numbers 1, 2, 3, 4, 5 and 6, and the edges are placed as a vector basis function: Nᵢ^{e}=Wᵢ_{₁}ᵢ_{₂}|ᵢ^{e}=(Lᵢ_{₁}^{e}∇Lᵢ_{₁}^{e}−Lᵢ_{₁}^{e}∇Lᵢ_{₁}^{e})|ᵢ^{e};

Among which, lᵢ^{e} represents a length of an ith edge; a unit vector e₁ is defined as a unit vector pointing from a node 1 to a node 2, and a gradient relative to gravity center coordinates can be described by following formulas e₁·∇L₁^{e}=−1/l₁² and e₁·∇L₂^{e}=1/l₁^{e}.

The integral region in the equation is divided into several sub-regions Ωₙ, and a matrix equation can be obtained by using the finite element analysis method; a left term of the matrix equation comprises two terms:

$${E}_{ij}^{e} = \int \int {\int }_{{V}^{o}} ( ∇ \times {N}_{i}^{e} ) \cdot ( ∇ \times {N}_{j}^{e} ) dV \\ {F}_{ij}^{e} = \int \int {\int }_{{V}^{e}} {N}_{i}^{e} \cdot {N}_{j}^{e} dV$$

a right term of the matrix equation is as follows:

b=−jk₀Z₀f_{edgek}Nₖ*d1=−jk₀Z₀ξ

According to the above equations, a sparse matrix equation Ax=b can be obtained. The matrix equation can be solved by multi frontal algorithm; solution resources used in this step can be a local computer or multi-computer parallel, which can be dynamically adjusted according to fitting results.

The multilevel distributed parallel computing method in the present invention also comprises recovering the solution results and fitting frequency response with a formula

$$f ( s ) \approx {\sum }_{n = 1}^{N} \frac{{c}_{n}}{s - {a}_{n}} + d + sh ,$$

where cₙ is a residue term and an is a pole;

The fitting process is that the left and right ends of the defined frequency response are multiplied by an unknown function

$$σ ( s ) = {\sum }_{n = 1}^{N} \frac{s - \overline{{a}_{n}}}{} + 1$$

at the same time, and an overdetermined matrix equation about unknown quantities cₙ, d, h, and [symbol] be obtained by substituting a few frequency points into the unknown function:

$$( {\sum }_{n = 1}^{N} \frac{{c}_{n}}{s - \overline{{a}_{n}}} + d + sh ) = ( {\sum }_{n = 1}^{N} \frac{s - \overline{{a}_{n}}}{} + 1 ) f ( s )$$

The unknown quantity obtained by solving can be used to describe the formula of frequency response:

$$f ( s ) = \frac{{( σ f )}_{fit} ( s )}{{σ}_{fit} ( s )} = h \frac{{\sum }_{n = 1}^{N + 1} ( s - {z}_{n} )}{{\sum }_{n = 1}^{N} ( s - )}$$

Using a solution of σ (s)=0 as a new pole, a new overdetermined matrix equation can be generated to solve the unknown quantities cₙ, d, and h.

The multilevel distributed parallel computing method in the present invention also comprises judging whether current results meets convergence conditions according to the convergence conditions specified by the user; If errors are large, according to the available computing resources, a number of frequency points are dynamically selected and allocated to the computing nodes; If the errors approach the convergence conditions, the number of frequency points to be solved is estimated, and node computing resources are dynamically allocated according to the number of frequency points and computing nodes, so that multiple computing nodes can solve the system matrix of a certain frequency point at the same time.

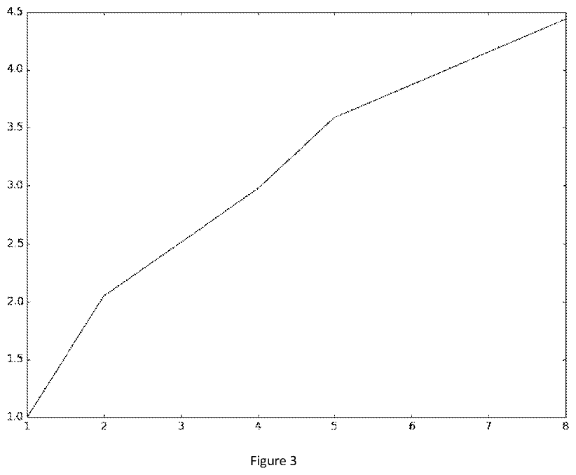

FIG. 3 shows acceleration efficiency of the method flow of the present invention, and it can be seen that calculation efficiency can be improved for several times with the same calculation resources.

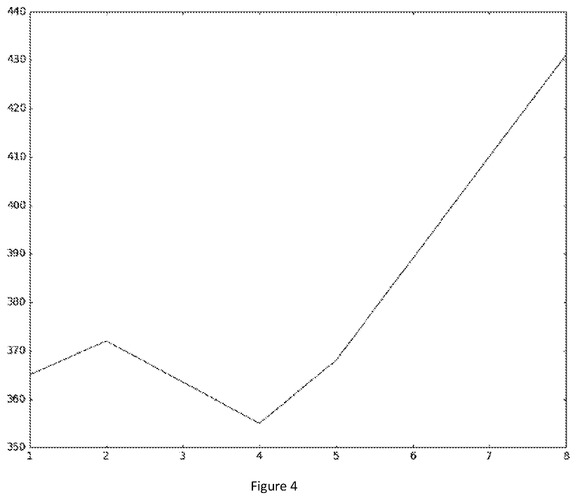

FIG. 4 shows the number of iterations of dynamic frequency points in the method flow of the present invention, and it can be seen that compared with the method of the matrix parallelization acceleration, the increase of the frequency points needed to be calculated by the present method is less.

FIG. 5 shows exact calculation results (the solid line *) and interpolation results (the dotted line). It can be seen that the accurate data of the whole frequency band can be interpolated through a small number of frequency points.

The above-mentioned embodiments only express certain implementations of the present invention, and the description thereof is specific and detailed, but it cannot be understood as limiting the patent scope of the present invention; it should be pointed out that for those skilled in the art, several variations and improvements can be made without departing from the concept of the present invention, which are within the protective scope of the present invention; therefore, the protective scope of the present invention patent should be based on the appended claims.

1-5. (canceled)

6. A multilevel distributed parallel computing method for integrated circuit board simulation, wherein the method comprises following steps:
(S100), calculating a number of nodes;
(S200), allocating tasks;
(S300), calculating and solving; and
(S400), judging convergence;
in the step (S300), calculating and solving comprises specifically solving distribution of electric fields and magnetic fields in the solution area at each of the computing nodes by a finite element method and extracting performance parameters of a circuit according to distribution of electromagnetic fields in a solution area for subsequent simulations;
wherein in the step (S300) the finite element method is used, specifically a finite element wave equation as shown here:
$${\int }_{Ω} {W}_{i} \cdot [ ∇ \times ( \frac{1}{{μ}_{r}} ∇ \times E ) - {k}_{0}^{2} {ε}_{r} E ] d Ω = - {jk}_{0} {Z}_{0} {\int }_{Ω} {W}_{i} \cdot {J}_{imp} d Ω ;$$
wherein the distribution in the solution area in step S300 comprises grid division of the solution area; the grid division of the solution area comprises tetrahedron division; and the tetrahedron division is as follows:
by introducing a barycentric coordinate system and taking a tetrahedron unit year as an example, four vertices of each tetrahedron can be expressed as: (L₁^{e}, L₂^{e}, L₃^{e}, L₄^{e}); the tetrahedron comprises six edges with serial numbers 1, 2, 3, 4, 5 and 6, and the edges are placed as a vector basis function: Nᵢ^{e}=Wᵢ_{₁}ᵢ_{₂}|ᵢ^{e}=(Lᵢ_{₁}^{e}∇Lᵢ_{₁}^{e}−Lᵢ_{₁}^{e}∇Lᵢ_{₁}^{e})|ᵢ^{e};
among which, lᵢ^{e} represents a length of an ith edge; a unit vector e₁ is defined as a unit vector pointing from a node 1 to a node 2, and a gradient relative to gravity center coordinates can be described by following formulas e₁·∇L₁^{e}=−1/l₁² and e₁·∇L₂^{e}=1/l₁^{e}; among which, ;ᵢ^{e} represents a length of an ith edge; a unit vector ei is defined as a unit vector pointing from a node 1 to a node 2, and a gradient relative to gravity center coordinates is described by following formulas e₁·∇L₁^{e}=−1/l₁² and e₁·∇L₂^{e}=1/l₁^{e}; wherein an integral region in the equation is divided into several sub-regions Ωₙ, and a matrix equation is obtainable by using the finite element analysis method; a left term of the matrix equation comprises two terms:
$${E}_{ij}^{e} = \int \int {\int }_{{V}^{o}} ( ∇ \times {N}_{i}^{e} ) \cdot ( ∇ \times {N}_{j}^{e} ) dV \\ {F}_{ij}^{e} = \int \int {\int }_{{V}^{e}} {N}_{i}^{e} \cdot {N}_{j}^{e} dV$$
a right term of the matrix equation is as follows:
b=−jk₀Z₀f_{edgek}Nₖ*d1=−jk₀Z₀ξ
according to the above equations, a sparse matrix equation Ax=b is obtained; the matrix equation is solved by multi frontal algorithm; by running solution resources used in this step in a local computer or multi-computer parallel, which is dynamically adjusted according to fitting results;
wherein the multilevel distributed parallel computing method also comprises recovering the solution results and fitting frequency response with a formula
$$f ( s ) \approx {\sum }_{n = 1}^{N} \frac{{c}_{n}}{s - {a}_{n}} + d + sh ,$$
where cₙ is a residue term and an is a pole;
a fitting process comprises multiplying a left end and a right end of the defined frequency response by an unknown function
$$σ ( s ) = {\sum }_{n = 1}^{N} \frac{s - \overline{{a}_{n}}}{} + 1$$
simultaneously, and an overdetermined matrix equation about unknown quantities cₙ, d, h, and [symbol] is obtained by substituting a few frequency points into the unknown function:
$$( {\sum }_{n = 1}^{N} \frac{{c}_{n}}{s - \overline{{a}_{n}}} ) = ( {\sum }_{n = 1}^{N} \frac{s - \overline{{a}_{n}}}{} + 1 ) f ( s )$$
an unknown quantity obtained by solving the unknown function is used to describe a formula of the frequency response:
$$f ( s ) = \frac{{( σ f )}_{fit} ( s )}{{σ}_{fit} ( s )} = h \frac{{\sum }_{n = 1}^{N + 1} ( s - {z}_{n} )}{{\sum }_{n = 1}^{N} ( s - )}$$
using a solution of σ (s)=0 as a new pole, a new overdetermined matrix equation can be generated to solve unknown quantities cₙ, d, and h.

7. The multilevel distributed parallel computing method for integrated circuit board simulation according to claim 6, wherein
in step (S100) calculating the number of nodes comprises specifically determining the number of nodes opened on corresponding computing nodes by taking user parameters and mesh generation results as inputs and estimating memory consumption and user control.

8. The multilevel distributed parallel computing method for integrated circuit board simulation according to claim 6, wherein
in the step (S200) allocating tasks comprises specifically, selecting appropriate simulation frequency points from simulation segments as required by users according to the number of nodes determined in the step (S100) and distributing to the computing nodes.

9. The multilevel distributed parallel computing method for integrated circuit board simulation according to claim 6, wherein
in the step (S400), the convergence judgment comprises specifically judging whether current results meet convergence conditions according to convergence conditions specified by the users.

10. The multilevel distributed parallel computing method for integrated circuit board simulation according to claim 9, wherein the multilevel distributed parallel computing method also comprises judging whether current results meets convergence conditions according to the convergence conditions specified by the users; If errors are large, according to the available computing resources, selecting dynamically a number of frequency points and allocating to the computing nodes; If the errors approach the convergence conditions, estimating the number of frequency points to be solved, and allocating dynamically node computing resources according to the number of frequency points and the computing nodes, so that multiple computing nodes can solve the system matrix of a certain frequency point simultaneously.
